(19) United States
(12) Patent Application Publication
(10) Pub. No.: US 2006/0170993 A1
(43) Pub. Date: Aug. 3, 2006

(54) Printer

(76) Inventor: Steve A. Jacob, Boise, ID (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/048,279

(22) Filed: Jan. 31, 2005

(51) Int. Cl. G03F 3/08

(52) U.S. Cl. 358/518

(57) ABSTRACT

First data is obtained that describes a reference printed reproduction of a color by a reference printer. Second data is obtained that describes a second printed reproduction of the color by a second printer. The first and second data is used to provide the second printer with a selectable option to output a third reproduction of the color. The color difference between the reference printed reproduction of the color and the second printed reproduction of the color is greater than a color difference between the reference printed reproduction of the color and the third reproduction of the color.

### BACKGROUND OF THE INVENTION

As used herein, the phrase “printer” refers to any device that includes a printing function. Thus, for example, the phrase “printer” may refer to an inkjet printer, a laser printer, a commercial printing press, a multifunction peripheral (MFP) that includes a printing function, etc. The phrase “color printer” refers to any type of printer that can generate color printed output.

Two printers may reproduce an original color differently and sometimes this can create a problem for the user. For example, in a commercial printing setting, a user may have been historically using a first color printer (printer “A”) to print documents for a customer. The customer is satisfied with the way printer “A” reproduces a particular original color, such as a color in a company logo, for example. The user may now wish to use a second color printer (printer “B”) to print documents for the same customer. Printer “B”, however, reproduces the particular original color differently than printer “A” and, as a result, the customer is dissatisfied.

The reader will note that the customer may be dissatisfied even if printer “B” reproduces the original color with higher accuracy as compared to printer “A”. Possible reasons for this possibility are that the customer has grown accustomed and/or subjectively prefers the way printer “A” reproduces the original color.

### BRIEF DESCRIPTION OF THE DRAWINGS

FIG. 1 shows a computing system;

FIG. 2 shows a simplified block diagram of a printer according to one embodiment;

FIG. 3A and FIG. 3B shows schematically some of the color conversions that may occur within an image pipeline;

FIG. 4 shows a printed page;

FIG. 5A-C is a flow diagram illustrating how a host application and a printer web service may configure a printer;

FIG. 6A-B each shows schematically how a look-up table may be defined;

FIG. 7 shows schematically some of the color conversions that may occur within an image pipeline; and

FIG. 8 shows a computer screen shot.

### DESCRIPTION

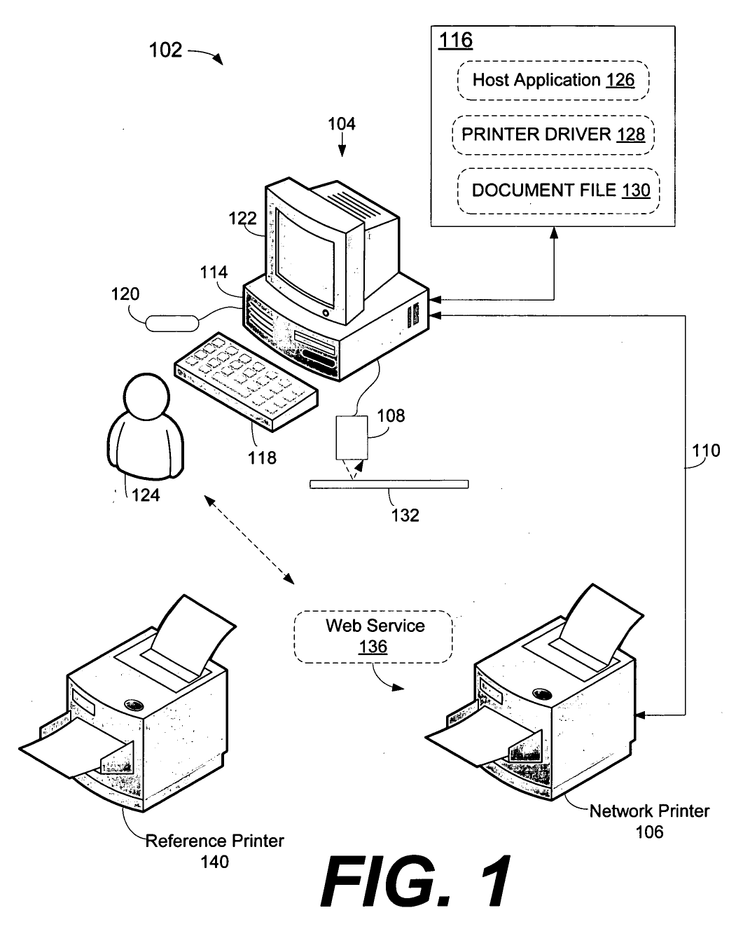

With reference to FIG. 1, shown is a computing system 102 that is in accordance with an example embodiment of the present invention. The computing system 102 includes a host computer 104, a network color printer 106, and a color measurement device 108. The host computer 104 and the network printer 106 are connected via a network 110.

The host computer 104 includes a central processing unit (CPU) 114, a memory 116, a keyboard 118, a computer mouse 120 and a display monitor 122. The display monitor 122 enables the host computer 104 to display a graphical user interface (GUI) to a user 124, as is described further below. The keyboard/mouse 118, 120 enable the user 124 to provide input to the host computer 104.

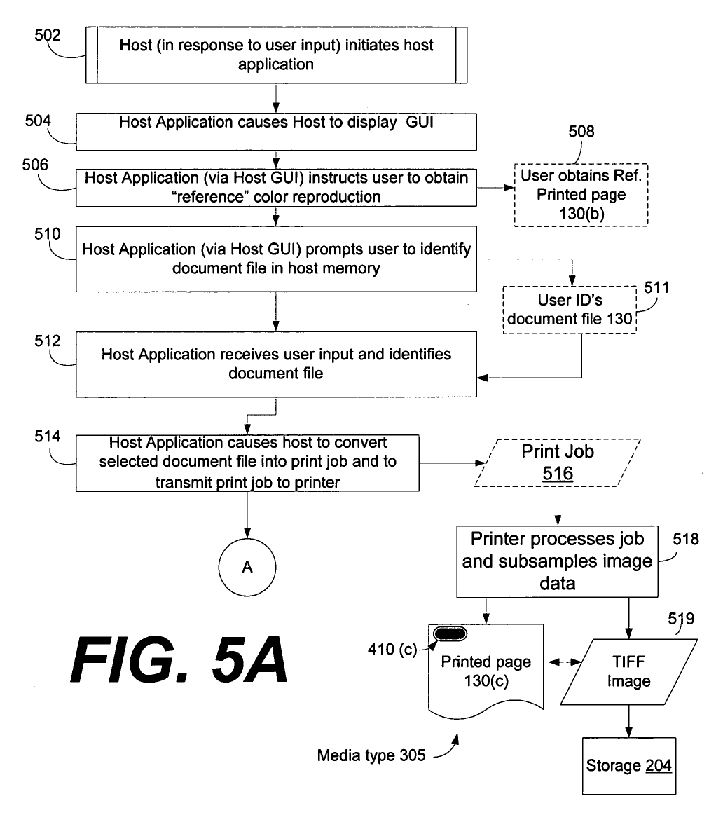

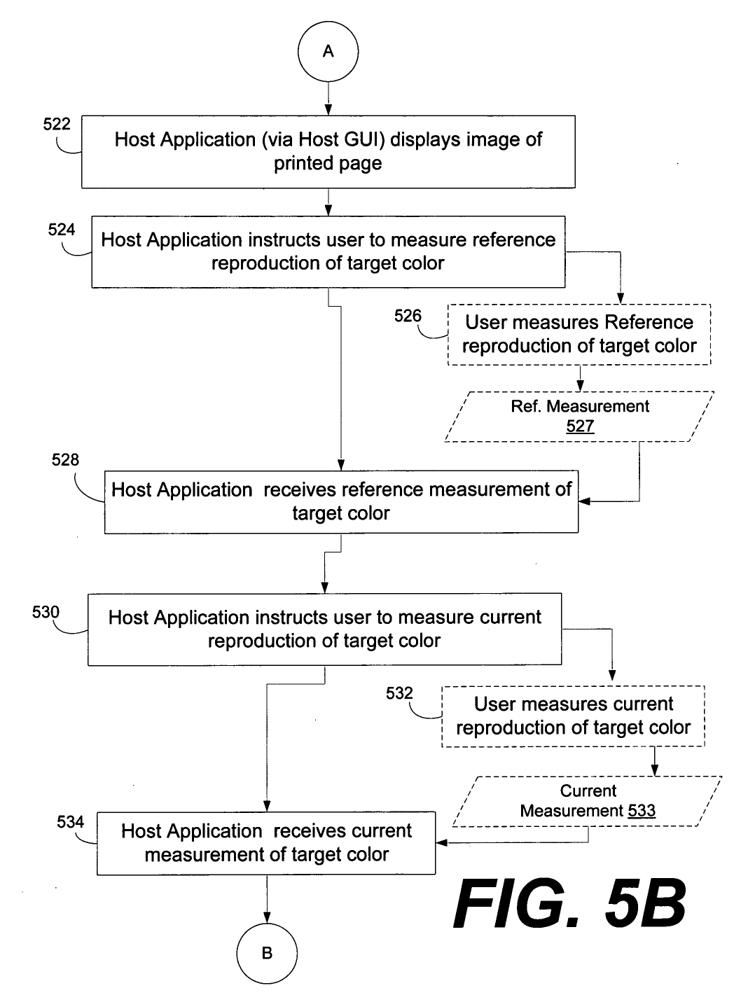

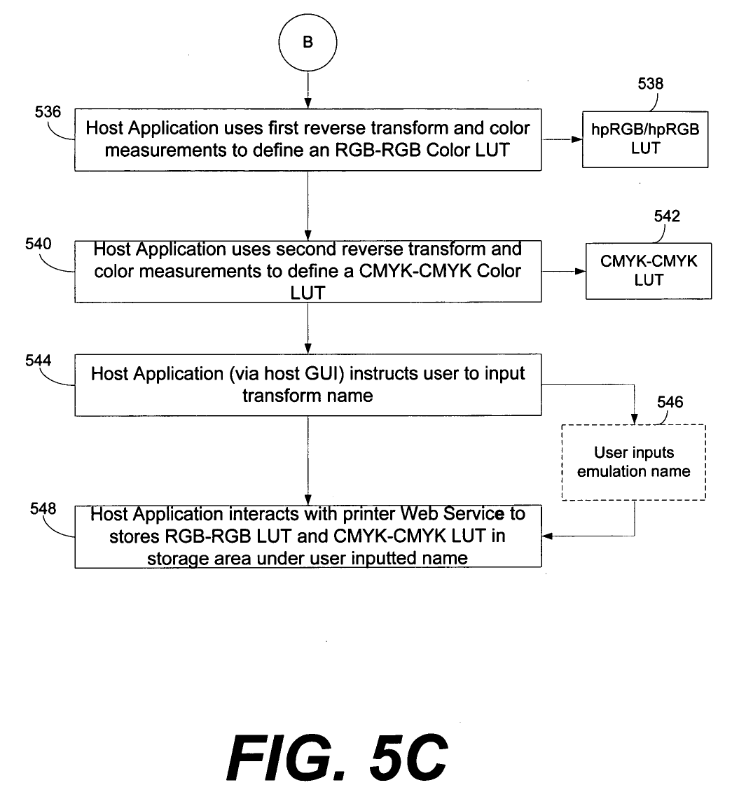

Stored in the host memory 116 is a host application 126, a print driver 128 and a document file 130. The host application 126 enables the host computer 104 to function as is described below in conjunction with FIG. 5A-C. The print driver 128 enables the host computer 104 to convert the document file 130 into a print job and to transmit the print job (over the network 110) to the network printer 106 for printing.

The color measurement device 108 may represent any device that can measure color at different locations on a printed medium (e.g., print medium 132) and that can output these measurements to the host computer 104. According to one specific implementation, for example, the color measurement device 108 is a handheld calorimeter that is connected to the host computer 104 via a communication cable. In such an implementation, the handheld colorimeter may output color measurements to the host computer 104 in the form of Commission International de l'Eclairage (CIE) XYZ tristimulus values, for example.

The network printer 106 is, in this example embodiment, a laser printer that uses an electrophotographic process to generate color printed output. As is discussed further below, the network printer 106 provides a web service 136. As is also discussed below, the host application 126 can interact with the web service 136 over the network 110.

Also shown in FIG. 1 is a second color printer 140 that we will refer to as the “reference printer”. The reference printer 140 may represent a commercial offset printing press, for example.

### Printer Construction

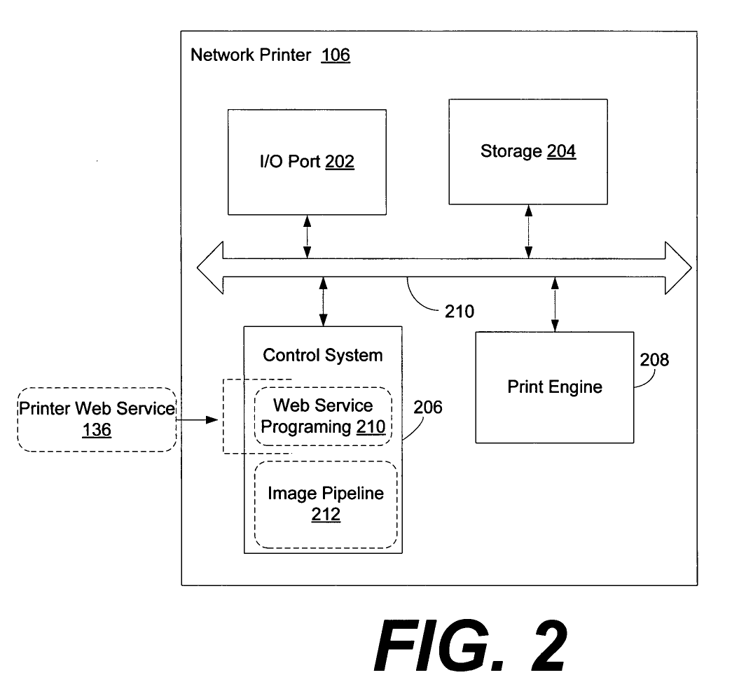

FIG. 2 shows a simplified block diagram of the network printer 106 according to one embodiment. As shown, the network printer 106 includes an I/O port 202, a mass storage area 204, a control system 206 and a print engine 208 all interconnected via a local bus system 210.

The I/O port 202 generally enables the network printer 106 to connect as well as communicate over the network 110. The mass storage area 204 generally provides the network printer 106 with the ability to store data, such as described below. According to one implementation, the mass storage area 204 may represent a magnetic and/or an optical disc storage drive.

The print engine 208 includes various components to implement an electro-photographic process to generate color printed output. In this example we will assume that the print engine 208 implements the electro-photographic process in part by transferring four different colors (in the form of colored toner) to a print medium. These colors are Cyan (C), Magenta (M), Yellow (Y) and Black (K). Accordingly, CMYK image data is used to drive the print engine 208.

The control system 206 generally controls the operation of the network printer 106 to generate printed output and to provide the printer web service 136. In this example, the control system 206 includes programming (web service programming 210) that can be executed by the control system 206 to provide the web service 136 using a client/server model.

Additionally, the control system 206 includes an image pipeline 212 for processing input image data received from a source (e.g., a host print driver) into CMYK data that is suitable to drive the print engine 208. The image pipeline 212 may be implemented in any suitable hardware, software and/or firmware, for example.

### Image Pipeline Color Conversions

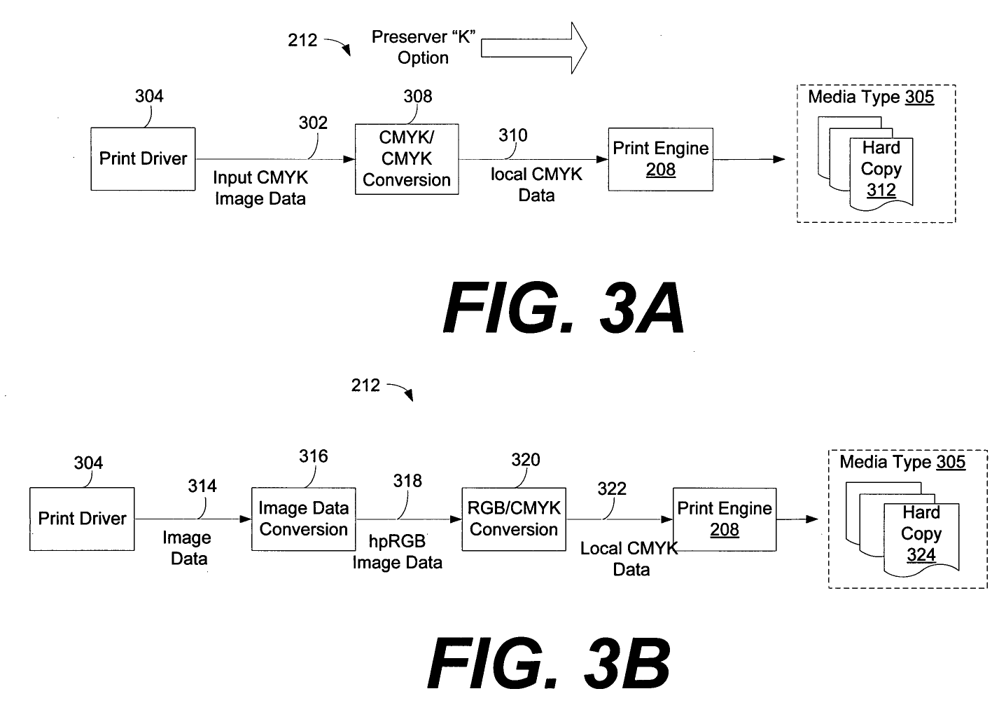

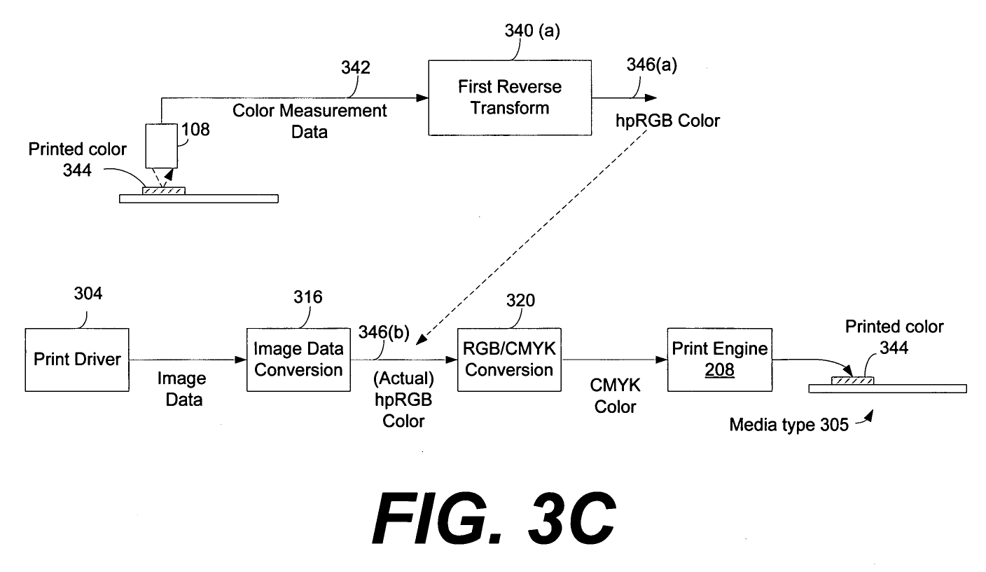

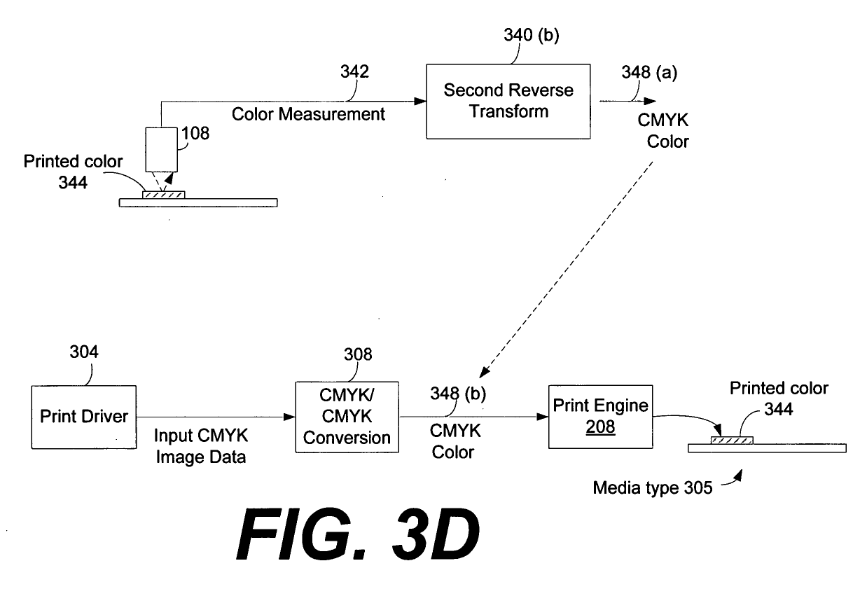

FIG. 3A and FIG. 3B shows schematically some of the color conversions that may occur within the image pipeline 212. In particular, FIG. 3A shows the case wherein input image data 302 (received from a print driver 304 and to be printed on a selected media type 305) is in a CMYK color space and an option (“preserve K option”) is selected to preserve black separation. As indicated in FIG. 3A, the pipeline 212 applies a CMYK-CMYK conversion 308 to the input image data 302 so as to generate image data 310 that is in a local CMYK space. The CMYK-CMYK conversion 308 may map, for example, out-of-gamut colors expressed in the input image data 302 to colors that are within the local gamut boundary of the network printer 106. The CMYK-CMYK conversion 308 may also limit the maximum amount of toner that is used by the print engine 208. The local CMYK image data 310 can be sent directly to the print engine 208 to generate printed output 312.

FIG. 3B shows the set of color conversions that may be applied by the image pipeline 212 when the preserve “K” option is not selected. As shown, input image data 314 (received from the print driver 304 and to be printed on the selected media type 305) is converted by input image data conversion 316 into image data 318 that is in a local color space of the network printer 106. In this example, the image data 316 is in an hpRGB local color space. The hpRGB image data 318 is then converted, by an RGB-CMYK color conversion 320, into local CMYK image data 322 that can be sent to the print engine 208 to generate printed output 324.

It is noted that both the CMYK-CMYK conversion 308 and the RGB-CMYK conversion 320 may account specifically for the particular characteristics of the selected media type 305. Accordingly, and as appreciated by a person skilled in the art, the image pipeline 212 may apply a different CMYK-CMYK conversion or a different RGB-CMYK conversion respectively if another media type is selected.

For the following discussion we will assume that the behavior of the image pipeline 212 is known to the extent that a first “reverse transform” 340(a) has been defined for the color conversions depicted in FIG. 3B. Also, a second reverse transform 340(b) has been defined for the color conversions depicted in FIG. 3A.

FIG. 3C shows schematically the first reverse transform 340(a) (which is unique for the RGB-CMYK conversion 320). As indicated in FIG. 3C, the first reverse transform 340(a) converts a color measurement (e.g., color measurement 342) that describes a particular printed color (e.g., printed color 344) into an estimate of the hpRGB color that would need to be provided as an input of the RGB/CMYK conversion 320 in order for the network printer 106 to output that printed color on the media type 305.

Thus, for example, assuming the color measurement 342 describes the printed color 344 perfectly and the first reverse transform 340(a) models the current behavior of the image pipeline 212 perfectly, the hpRGB color 346(a) that is outputted by the first reverse transform 340(a) should match the hpRGB color 346(b). The hpRGB color 346(b) being the actual hpRGB color that would need to be applied as an input to the RGB/CMYK conversion 320 in order for the printer 106 to output the printed color 344 on the selected media type 305.

FIG. 3D shows schematically the second reverse transform 340(b). As indicated in FIG. 3D, the second reverse transform converts a color measurement (e.g., color measurement 342) that describes a particular printed color (e.g., printed color 344) into an estimate of the CMYK color that would be generated by the CMYK/CMYK conversion 308 in order for the printer 106 to output the printed color 344 on the selected media type 305.

Thus, assuming the color measurement 342 describes the printed color 344 perfectly and the second reverse transform 340(b) models the behavior of the image pipeline 212 perfectly, the CMYK color 348(a) should match the CMYK color 348(b) that would be generated by the CMYK/CMYK conversion 308 in order for the printer 106 to output the printed color 344 on the selected media type 305.

The use of these two reverse transforms 340(a), 340(b) are describe below.

### Reference Printer Reproduction of Document File

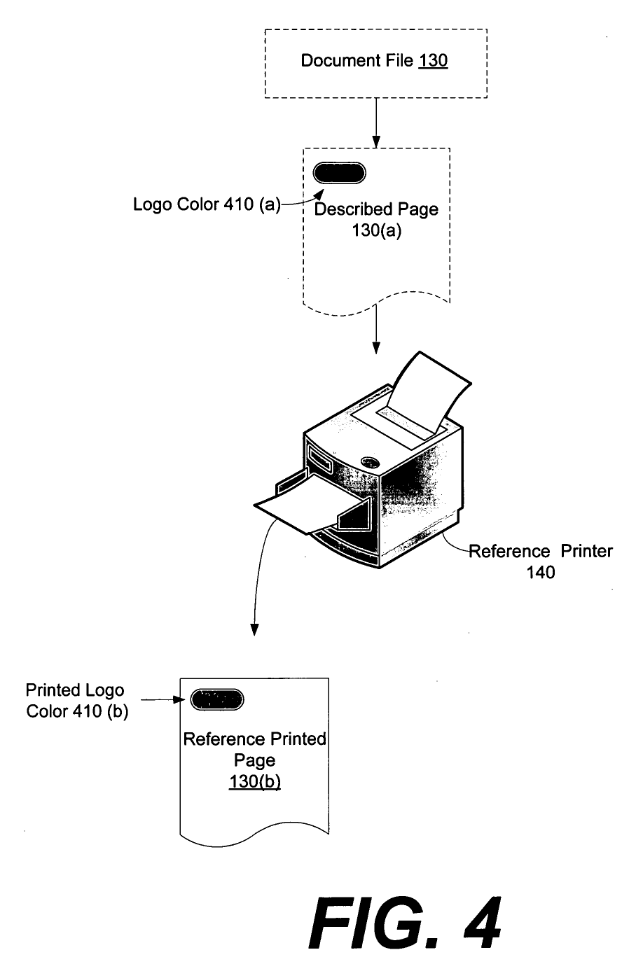

As indicated in FIG. 4, we will (in order to simplify the following description) assume that the document file 130 describes a single page 130(a). The single page 130 includes a color 410(a) in a company logo that is located as shown in the upper left hand corner of the single page 130(a).

We will further assume that the reference printer 140 has previously been used to print the document file 130 thereby generate a printed page 130(b). For ease of discussion, we will refer to the printed page 130(b) as the “reference printed page 130(b)”.

As shown, the reference printed page 130(b) includes a printed reproduction of the logo color 410(b). We will refer to this particular reproduction of the logo color 410 as the “reference” printed logo color 410(b).

### Use of Host Application and Printer Web Service

FIG. 5A-C is a flow diagram illustrating, by way of example, how the user 124 may use the host application 126 and the printer web service 136 to configure the network printer 106 with the optional capability to emulate a different printer reproduction of a particular color. To illustrate by way of a specific example, we will assume in the following discussion that the user 124 desires to use the host application/printer web service to provide the network printer 106 with the capability to emulate the reference printer 140 reproduction of the logo color 410(b).

Beginning at step 502, the user 124 interacts with the host computer 104 to run the host application 126.

At step 504, the host application 126 displays a graphical user interface (GUI). The GUI may be in the form of one or more dialog boxes that are displayed automatically (as needed) on the host computer 104.

At step 506, the host application 126 (via the host GUI) instructs the user to obtain a “reference” printed reproduction of a target color the user desires the network printer 106 to emulate.

In response to this instruction, at step 508 the user 124 obtains the reference printed page 130(b). The reader will recall that the reference printed page 130(b) includes the reference printed logo color 410(b).

At step 510, the host application 126 (via the host GUI) instructs the user to provide input (via the host GUI) that identifies the document file in the host computer file system that was used to print the reference printed reproduction of the target color.

The reader will recall that the document file 130 was used to print the reference printed page 130(b). At step 511, therefore, the user 124 follows the host application instruction and provides input (via the host GUI) that identifies the document file 130. At step 512 the host application 126, in response to the user input, identifies the document file 130.

At step 514, the host application 126 causes the host to convert the identified document file (i.e., document file 130) into a print job 516 and to transmit the print job 516 to the network printer 106. This step may be accomplished by the host application 126 interacting with the print driver 128 as well as the native application (not shown in FIG. 1) of the document file.

At step 518, the network printer 106 receives the print job 516 and processes the job into a printed page 130(c) that includes a printed logo color 410(c). The printed logo color 410(c) is a reproduction, by the network printer 106, of the logo color 410. We will assume that there is a difference (ΔE)₁ in color between the printed logo color 410(c) and the reference printed logo color 410(b).

In this example, we will also assume that the print job 516 is configured so that the network printer 106 is responsive to the job by applying the color conversions shown in FIG. 3B and prints the job using the media type 305. Thus, the image data in the print job 516 is converted by the image pipeline 212 to hpRGB image data, and then to CMYK image data.

Furthermore, we will also assume the print job 516 includes a special command that causes the network printer 106 to sub-sample the hpRGB image data that is generated by the image pipeline 212 as it processes the image data in the print job 516. This results in a TIFF file 519 being created that comprises the sub-sampled hpRGB data. The TIFF file 519 is stored in the printer storage area 204.

At step 522, the host application 126 interacts with the web service programming 210 to retrieve data that describes an image of the printed page 130 (c). The TIFF file 519 may be used as the source of this data. The host application 126 then displays (via the host GUI) an image of the printed page 130(c). The host GUI may continue to display the image of the printed page 130(c) as the rest of the steps described below are performed.

At step 524, the host application 126 instructs (via the host GUI) the user to measure the reference reproduction of the target color(s) that the user obtained at step 508.

In response to this instruction, at step 526, the user 124 operates the color measurement system 108 to measure the reference printed logo color 410(b) that is printed on the reference printed page 130(b). This results in a reference logo color measurement 527 being generated.

At step 528, the host application 126 receives and stores the reference logo color measurement 527.

At step 530, the host application 126 (via the host GUI) instructs the user to measure the reproduction of the target color as produced by the network printer 106 at step 518.

In response to this instruction, at step 532, the user 124 operates the color measurement system 108 to measure the printed logo color 410(c) that was printed by the network printer 106 at step 518. This results in a second color measurement 533 being generated that describes the color of the logo color as reproduced by the network printer 106. For ease of discussion, we will refer to the second color measurement 533 as the “current” logo color measurement 533 as this color measurement represents the current behavior of the network printer 106 to reproduce the logo color. At step 534, the host application 126 receives and stores the current logo color measurement 533.

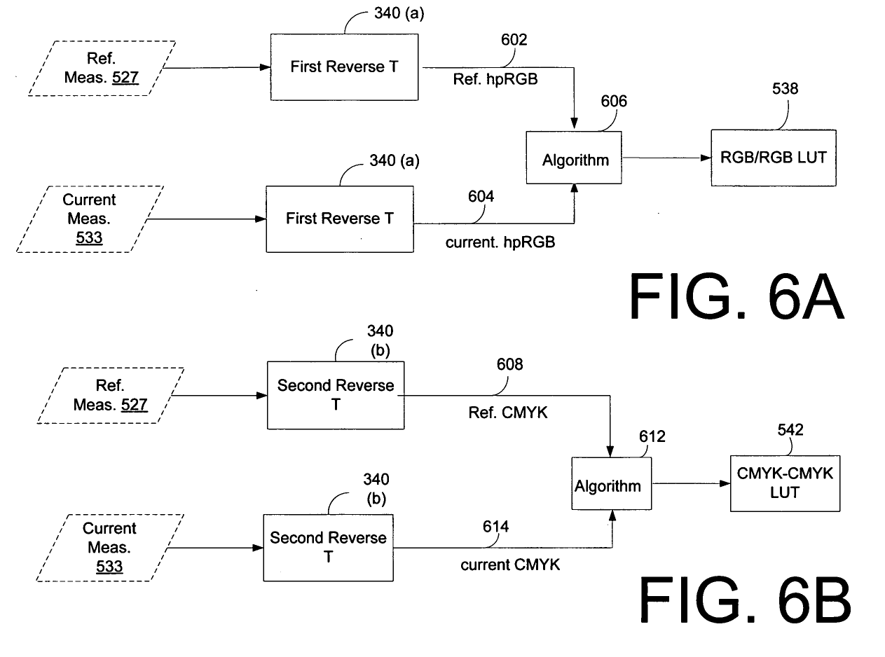

At step 536, the host application 126 uses the first reverse transform 340(a), the reference logo color measurement 527 and the current logo color measurement 533 to define an hpRGB-hpRGB look-up table (LUT) 538. This step is described further below in conjunction with FIG. 6A.

At step 540, the host application 126 uses the second reverse transform 340 (b), the reference logo color measurement 527 and the current logo color measurement 533 to define a CMYK-CMYK look-up table 542. This step is described further below in conjunction with FIG. 6B.

At step 544, the host application 126 (via the host GUI), instructs the user to input a name that will be assigned to the two look-up tables. At step 546, the user 124 follows the instruction and inputs a desired name (e.g., “Steve's logo color emulation”).

At step 548, the host application 126 receives the desired name and interacts with the web service programming 210 to store the two look-up tables 538, 542 into the printer storage area 204 under the desired name. As discussed further below, the two look up-tables 538, 542 provide the network printer 106 with the optional capability to emulate the reference printer 140 reproduction of the logo color.

FIG. 6A shows schematically how the RGB/RGB LUT 538 may be defined at step 536. As shown, the first reverse transform 340(a) is used to transform the reference logo color measurement 527 to a “reference” hpRGB logo color 602. The reader will note that the reference hpRGB logo color 602 represents an estimate of the hpRGB color that would need to be provided as an input of the RGB/CMYK conversion 320 in order for the network printer 106 to output the reference printed logo color 410(b) on the media type 305.

Additionally, the first reverse transform 340(a) is used to transform the current logo color measurement 533 to a “current” hpRGB logo color 604. The “current” hpRGB logo color 604 represents an estimate of the hpRGB color that was provided as an input of the RGB/CMYK conversion 320 in order for the network printer 106 to output the printed logo color 410(c) at step 518.

As shown, the reference hpRGB logo color 602 and the current hpRGB logo color 604 may then be used as inputs to a pre-defined algorithm 606 that generates the RGB/RGB LUT 538. The pre-defined algorithm 606 may operate to identify the tetrahedron nodes that surround the current hpRGB logo color 604 and define the RGB/RGB LUT 538 to shift these particular nodes to contain the reference hpRGB logo color 602. The RGB/RGB LUT 538 may also be defined to blend nodes in proximity to the shifted nodes so as to minimize transition artifacts when the RGB/RGB LUT 538 is used.

FIG. 6B shows schematically how the CMYK-CMYK LUT 542 may be defined at step 540. As shown, the second reverse transform 340(b) is used to transform the reference logo color measurement 527 and the current logo color measurement 533 respectively to a “reference” CMYK logo color 608 and a current CMYK color 614. The reader will note that the reference CMYK logo color 608 represents an estimate of the CMYK color would be produced by the CMYK/CMYK conversion 308 in order for the network printer 106 to output the reference printed logo color 410(b) on the media type 305. The current CMYK color 614 represents an estimate of the CMYK color that would be produced by the CMYK/CMYK conversion 308 in order for the network printer 106 to output the printed logo color 410(c) on the media type 305.

As shown, the current CMYK color 614 and the reference CMYK color 608 may then be used as inputs to a pre-defined algorithm 612 that generates the CMYK/CMYK LUT 542. The pre-defined algorithm 612 may operate to identify the tetrahedron nodes that surround the current CMYK color 614 and define the CMYK/CMYK LUT 542 to shift these particular nodes to contain the reference CMYK color 608. The CMYK/CMYK LUT 542 may also be defined to blend nodes in proximity to the shifted nodes so as to minimize transition artifacts.

### Use of Look-Up Tables

After the RGB-RGB LUT 538 and the CMYK-CMYK LUT 542 are defined and stored at step 548 under the user inputted name (e.g., Steve's logo color emulation), the user 124 may thereafter optionally cause the network printer 106 to use these look-up tables so as to enable the network printer 106 to emulate the reference printer 140 reproduction of the printed logo color 410(b).

According to one embodiment, for example, the print driver 128 may operate (at the request of the user) to query the network printer 106 to retrieve a list of printer capabilities. The list may include the one or more emulation options each previously established by the user 124 in a similar manner as described above in connection with FIG. 5A-C. Each option may be identified in the list by the corresponding name (e.g., Steve's logo color emulation) that was inputted by the user (e.g., via step 548). When a user is setting up a print job, the print driver 128 may display the list of printer options to the user and allow a user to select an emulation option from the list. The print driver 128 is responsive to the selection by generating a print job that directs the network printer to apply the selected emulation option when printing the job. The print job may identify this option by the emulation name (e.g., Steve's logo color Emulation ) that was inputted by the user at step 546.

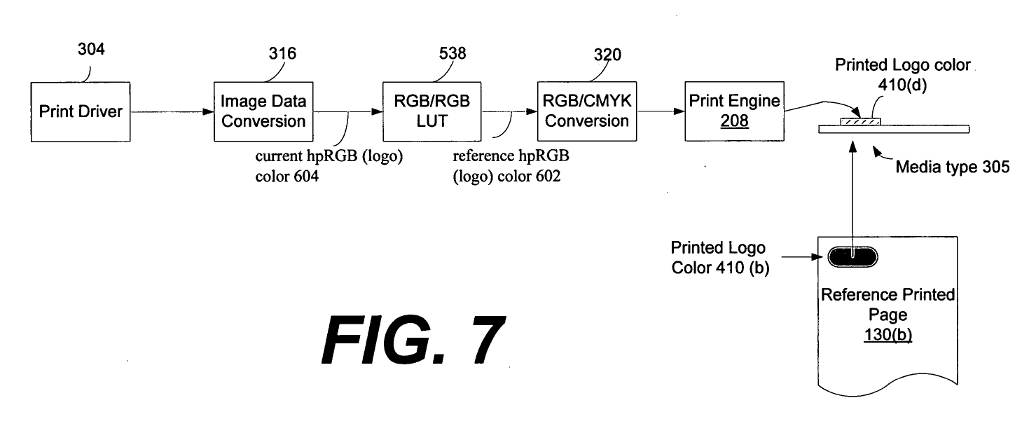

FIG. 7 illustrates the pipeline 212 color conversions assuming a print job selects the emulation option that was set-up in FIG. 5 and the color conversions shown in FIG. 3B are used to process the image data in the job. As shown, the RGB-RGB LUT 538 is logically placed (in response to the emulation option being selected) between the image data conversion 316 and the RGB/CMYK conversion 320. As indicated in FIG. 7, the RGB-RGB LUT 538 operates to map, for example, the current hpRGB (logo) color 604 to the reference hpRGB (logo) color 602.

From the foregoing, the reader will note that the RGB-RGB LUT 538 affects the behavior of the image pipeline 212 so that the network printer 106 outputs a printed logo color 410(d) on the media type 305 and the following relationship is true: (ΔE)₁>(ΔE)₂.

Wherein as previously noted “(ΔE)₁” represents the color difference (e.g., the CIE94 color difference) between the reference printed logo color 410(b) and the printed logo color 410(c) that was printed by the printer 106 at step 518 (without using the RGB/RGB LUT 538). And wherein “(ΔE)₂” represents the color difference between the reference printed logo color 410(b) and the printed logo color 410(d) that is printed by the network printer 106 using the RGB/RGB LUT 538. Thus, the printed logo color 410(d) is a closer match (in color) to the reference printed logo color 410(b) than the printed logo color 410(c) printed at step 518.

### Alternative Embodiments

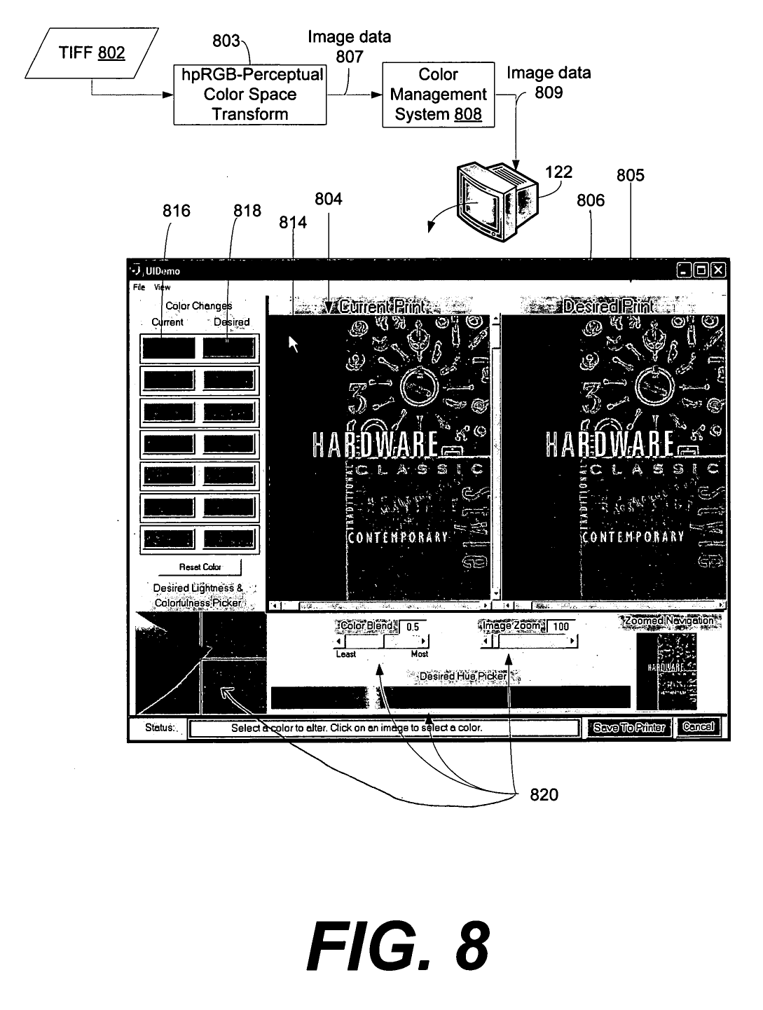

FIG. 8 shows a screen shot that is used to discuss another embodiment of the present invention. In this example embodiment, a print job that describes a document is transmitted to the network printer 106 (as in step 514 described above). The image data in the print job is processed and a TIFF file 802 is created (as in step 518).

In this embodiment, however, the host application displays a GUI 806 that includes a first image (current image 804) and an identical second image (desired image 805). The TIFF file 802 may be used as the source file for both images 804, 805. When the GUI 806 is first displayed the colors of both images 804, 805 are identical and correspond to the way the printer 106 would actually reproduce these colors. To display these colors in this manner, the TIFF file 802 may be first processed through a first transform 803 that converts the hpRGB data in the TIFF file 802 into image data 807. The image data 807 may be in a perceptual color space such as a CIELAB color space or an XYZ color space, for example. The image data 807 may be further processed through a color management system 808 that outputs image data 809 that is used to drive the host display. The color management system 808 may correct for the particular characteristics of the host computer 104.

A user may “point and click” (using the mouse 120) at any position (e.g., image position 814) in the current image 804 in order to select a color located at that position. Selecting a color in this manner results in a first bar 816 of the selected color and an identical second bar 818 of the selected color being displayed as shown. The user may select additional colors in this same manner.

The user may then interact with various color controls 820 to modify the displayed color of the second bar 818 to a color that matches a desired “reference” printed reproduction of that color. Thus, for example, the user may modify the second bar 818 to match the reference reproduction of the logo color 410(b), for example. As the user modifies the second bar color, the corresponding color in the “desired image 805” also changes to provide the user with visual feedback. In this example, however, the color of the first bar 816 and the current image 804 do not change.

Once the second bar 818 is modified to the desired color, the user may then select the “save to printer” option.

Upon selecting this option, the TIFF file 802 is used to obtain a “current” hpRGB color that corresponds to the original selected color as indicated by the first bar 814 and the corresponding color in the current image 804. A “reference” hpRGB color is also determined that corresponds to the present color (as modified by the user) of the second bar 818 and the corresponding color in the desired image 805.

The “reference” hpRGB color may be determined by applying a reverse transform to the host image data that describes the color of the second bar color bar 818. The reverse transform converts the host image data into a corresponding “reference hpRGB” color. An hpRGB-hpRGB LUT and a CMYK-CMYK LUT may then be defined using the reference hpRGB color and the current hpRGB color in a similar manner as is described above.

It is further noted that the present invention may be embodied in the form of a “computer-readable medium”. As used herein, the phrase “computer readable medium” can refer to any medium that can contain, store or propagate computer executable instructions. Thus, in this document, the phrase “computer-readable medium” may refer to a medium such as an optical storage device (e.g., a CD ROM) or a magnetic storage device (e.g., a magnetic tape). The phrase “computer-readable medium” may also refer to signals that are used to propagate the computer executable instructions over a network or a network system, such as the Public Internet.

Thus, a memory component (e.g., a memory storing the host application 126) that stores computer executable instructions may represent an embodiment of the invention. Furthermore, signals used to propagate the firmware over a communication link (e.g. an intranet, Public Internet, etc) may also represent an embodiment of the invention.

Although several specific embodiments of the invention have been described and illustrated, the invention is not to be limited to specific forms or arrangements of parts so described and illustrated. For example, the host application 126 described above could allow a user to set-up the network printer 106 to emulate more than one printer reproduction of a color.

The invention is limited only by the claims and the equivalents thereof.

1. A method, comprising:
(a) obtaining first data that describes a reference printed reproduction of a color by a reference printer;
(b) obtaining second data that describes a second printed reproduction of the color by a second printer; and
(c) using the first data and the second data to provide the second printer with a selectable option to output a third reproduction of the color;
wherein a color difference between the reference printed reproduction of the color and the second printed reproduction of the color is greater than a color difference between the reference printed reproduction of the color and the third reproduction of the color.

2. The method of claim 1, wherein the first data describes a color measurement of the reference printed reproduction of the color and the second data describes a color measurement of the second printed reproduction of the color.

3. The method of claim 1,
wherein the second printer includes an image pipeline; and
wherein the using step includes:
determining a reference color that would be produced within the image pipeline in order for the second printer to output the reference printed reproduction of the color;
determining a second color that was produced within the image pipeline in order for the second printer to output the second printed reproduction of the color;
defining a transform that transforms the second color into the reference color;
wherein the second printer uses the transform to output the third reproduction of the color.

4. The method of claim 1, wherein the reference color and the second color are each in a color space that is local to the color printer.

5. The method of claim 1, wherein the reference color and the second color are each in an hpRGB color space.

6. The method of claim 1, wherein the transform is an hpRGB-hpRGB look-up table.

7. The method of claim 2, wherein the second printer includes a print engine and an image pipeline capable of applying at least a first color conversion to input colors in order to produce CMYK data for transmission to the print engine; wherein the using step includes:
using the first data to estimate a reference input color that, when applied to the first color conversion, results in CMYK data being generated that causes the print engine to output the reference printed reproduction of the color on a first media type; and
using the second data to estimate a second input color that, when applied to the first color conversion, results in CMYK data being generated that causes the print engine to output the second printed reproduction on the first media type;
defining a look-up table that converts the second input color into the reference input color.

8. In a host computer connected to a printer, a method, comprising:
obtaining first data that describes a first printed reproduction of the color by the printer;
obtaining second data that describes a reference printed reproduction of the color by a different printer;
using the first color measurement and the reference color measurement to define a color transform that can be used by the printer to reprint the color; and
wherein the reprinted color is a closer match to the reference printed reproduction of the color than the first printed reproduction of the color.

9. The method of claim 8,
wherein the first data describes a first color measurement of the first printed reproduction of the color; and
wherein the second data describes a second color measurement of the reference printed color.

10. The method of claim 9, further comprising:
prompting a user to perform the first color measurement and the reference color measurement.

11. The method of claim 10,
wherein the first color measurement obtaining step includes: receiving the first color measurement from a handheld color measurement device;
wherein the reference color measurement obtaining step includes:
receiving the reference color measurement from the handheld color measurement device.

12. The method of claim 11, further comprising:
causing the printer to output the first printed reproduction of the color by transmitting a print job to the printer;
wherein the print job describes a page that includes the color and the printer is responsive to the print job by printing the page and where the printed page includes the first printed reproduction of the color.

13. The method of claim 12,
wherein the print job includes a command that causes the printer to generate a TIFF file that describes the page; and
wherein the method further includes:
receiving data, derived from the TIFF file, that describes the page; and
displaying, using the data, the page.

14. The method of claim 13, wherein the displayed page is a realistic representation of the page as printed by the printer.

15. A host computer, comprising:
means for obtaining first data that describes a first printed reproduction of a color by a first printer;
means for obtaining second data that describes a reference printed reproduction of the color by a second printer;
means for processing the first and second data to define a color transform that can be used by the first printer to reprint the color; and
wherein the reprinted color is a closer match to the reference printed reproduction of the color than the first printed reproduction of the color.

16. The host computer of claim 15, wherein the first data is a color measurement of the first printed reproduction of the color.

17. The host computer of claim 15, wherein the second data is a color measurement of the reference printed reproduction of the color.

18. The host computer of claim 15, wherein the color transform is an look-up table for mapping hpRGB data.
